(19) United States
(12) Patent Application Publication
(10) Pub. No.: US 2012/0018883 A1
(43) Pub. Date: Jan. 26, 2012

(54) CONDUCTIVE STRUCTURE FOR A SEMICONDUCTOR INTEGRATED CIRCUIT

(76) Inventors: Geng-Shin Shen, Hsinchu (TW); Jhong Bang Chyi, Hsinchu (TW)

(21) Appl. No.: 13/248,683

(22) Filed: Sep. 29, 2011

Related U.S. Application Data
(63) Continuation-in-part of application No. 11/898,613, filed on Sep. 13, 2007.

(51) Int. Cl. H01L 23/498

(52) U.S. Cl. 257/737; 257/E23.068

(57) ABSTRACT

A conductive structure for a semiconductor integrated circuit is provided. The semiconductor integrated circuit has a substrate, a plurality of pads and a passivation layer. The pads are disposed on the substrate. The passivation layer extends over and covers a part of the substrate and a part of around each of the pads to define a plurality of openings, in which the conductive structure electrically connects to a corresponding pad of the pads through a corresponding opening of the openings. The conductive structure includes a buffering layer, an under bump metallurgy (UBM) layer and a bump. The buffering layer is formed on the passivation layer without fully blocking the corresponding opening. The UBM layer is substantially formed in the corresponding opening and electrically connects to the corresponding pad. Additionally, the UBM layer, formed under the bump, continuously extends over and covers a peripheral portion of the buffering layer.

### CROSS-REFERENCES TO RELATED APPLICATIONS

This application is a continuation-in-part of application Ser. No. 11/898,613 filed Sep. 13, 2007, the contents of which are hereby incorporated by reference.

### BACKGROUND OF THE INVENTION

1. Field of the Invention

The present invention relates to a conductive structure. More particularly, the present invention relates to a conductive structure for a semiconductor integrated circuit.

2. Descriptions of the Related Art

A number of bump electroplating technologies have been applied in the fields of microelectronics and micro systems. Such bump electroplating technologies are applicable to various stages of many processes, such as establishing a connection between a flat panel display and a driver IC, carrying out technologies for conductive lines and air bridges on a gallium arsenide chip, and fabricating X-ray masks when using LIGA technology.

For example, in connecting the circuit board to the IC package, the IC package may be connected to the circuit board in a variety of ways. Usually, the IC pads of the IC package can be electrically connected to the circuit board using bump (especially gold bump) electroplating technology. Such a technology not only substantially reduces the size of the ICs, but also allows them to be directly embedded into the circuit boards, thus, reducing the space, dissipating the heat and resulting in low induction. In addition, the low cost of the electroplating process has made bump electroplating technology a favorable development.

Typical bump electroplating processes, such as the gold bump electroplating process, require the preparation of an under bump metal on the pads, which serves not only as an adhesion layer between the bumps and the pads but also as a conductive medium subsequent to formation of the bumps. As a result, the bumps can be successfully formed on such an under bump metal and be electrically connected to the pads therethrough.

However, in the conventional conductive structure of the IC packaging, the capability of the junction buffer of the bump on the UBM is limited in structure and material. In addition, the conductive area of the pad is decided before packaging. Once the process proceeds with poor control or improper selections of the materials, a breakage may occur due to the poor junction in the bump. As a result, the bump may peel off and cause the semiconductor chip to fail.

Furthermore, when the bump of the conductive structure of the IC package are connected to the circuit board, the thermal stress would be generated and the stress fatigue would occur in the connection interface between the IC package and the circuit board due to the Coefficient of Thermal Expansion (CTE) difference between the IC package and the circuit board. The electrical connection between the IC package and the circuit board would become unstable, which deteriorates and the quality of IC package.

Accordingly, providing a conductive structure having a reliable connection with the semiconductor integrated circuit and thus avoiding peeling, breakage and high thermal stress is highly desired in the semiconductor industry.

### SUMMARY OF THE INVENTION

One objective of this invention is to provide a conductive structure for a semiconductor integrated circuit to avoid the bump of the conductive structure peeling or the unstably electrical connection between the semiconductor integrated circuit and a circuit board.

To achieve the aforesaid objective, the conductive structure for a semiconductor integrated circuit of present invention has a substrate, a plurality of pads and a passivation layer. The pads are disposed on the substrate. The passivation layer extends over and covers a part of the substrate and around each pad in order to define a plurality of openings on the substrate. Further, the conductive structure electrically connects to a corresponding pad through a corresponding opening of the openings. The conductive structure comprises a buffering layer, an under bump metallurgy (UBM) layer and a bump. The buffering layer is formed on the passivation layer without fully blocking the corresponding opening, and the buffering layer can either be partially formed on the corresponding pad to cover a part of the corresponding opening or only formed on the passivation layer. The UBM layer is substantially formed in the corresponding opening for electrically connecting to the corresponding pad. Additionally, the UBM layer, formed with the bump, continuously extends over and covers a peripheral portion of the buffering layer.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1(a) is a schematic view of a semiconductor integrated circuit with the conductive structure in accordance with the first embodiment of this invention;

FIG. 1(b) is a cross-sectional view along a line A-A′ of FIG. 1(a);

FIG. 2(a) is a schematic view of a semiconductor integrated circuit in accordance with the conductive structure in accordance with the second embodiment of this invention;

FIG. 2(b) is a cross-sectional view along a line B-B′ of FIG. 2(a);

FIG. 3(a) is a schematic view of a semiconductor integrated circuit in accordance with the conductive structure in accordance with the third embodiment of this invention;

FIG. 3(b) is a cross-sectional view along a line C-C′ of FIG. 3(a);

FIG. 4(a) is a schematic view of a semiconductor integrated circuit in accordance with the conductive structure in accordance with the fourth embodiment of this invention;

FIG. 4(b) is a cross-sectional view along a line D-D′ of FIG. 4(a);

FIG. 5(a) is a schematic view of a semiconductor integrated circuit with the conductive structure in accordance with the fifth embodiment of this invention;

FIG. 5(b) is a cross-sectional view along a line E-E′ of FIG. 5(a);

FIG. 6(a) is a schematic view of a semiconductor integrated circuit in accordance with the conductive structure in accordance with the sixth embodiment of this invention;

FIG. 6(b) is a cross-sectional view along a line F-F′ of FIG. 6(a); and

FIGS. 7(a) to 7(h) depicted a process flow for forming the conductive structure on the semiconductor integrated circuit in accordance with the first embodiment of this invention.

### DESCRIPTION OF THE PREFERRED EMBODIMENT

In the following descriptions, this invention will be explained with reference to embodiments thereof, which relate to a conductive structure for a semiconductor integrated circuit. However, these embodiments are not intended to limit this invention to any specific environment, applications or particular implementations described in these embodiments. Therefore, descriptions of these embodiments are only for illustration purposes rather than limitation. It should be appreciated that in the following embodiments and the attached drawings, elements unrelated to this invention are omitted from depiction; and dimensional relationships among individual elements in the attached drawings are depicted in an exaggerative way for ease of understanding.

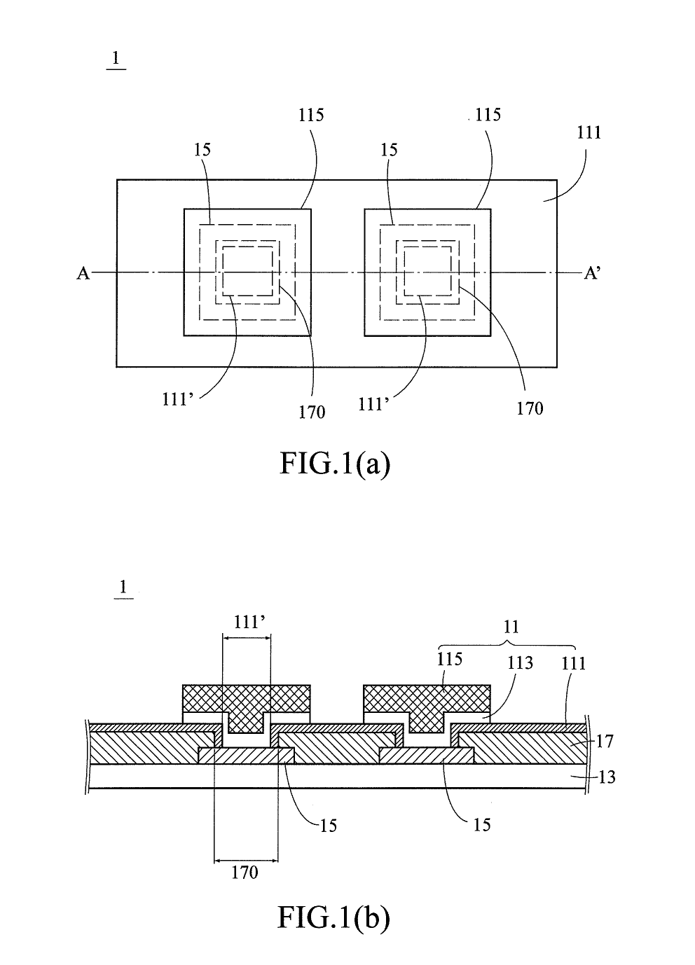

FIGS. 1(a) and 1(b) shows a semiconductor integrated circuit 1 with the conductive structure 11 of the first embodiment in accordance of the present invention. The semiconductor integrated circuit 1 has a substrate 13, a plurality of pads 15 and a passivation layer 17. As the cross sectional view along a line A-A′ of FIG. 1(a) shown in FIG. 1(b), the pads 15 (only two pads shown) are disposed on the substrate 13. The passivation layer 17 extends over and covers a part of the substrate 13 and around each pad 15 in order to define a plurality of openings 170 on the substrate 13. In this embodiment, as shown in the drawings, each of the openings 170 is a rectangle and the passivation layer 17 covers around of the openings 170, which means that the four sides of the rectangular openings 170 are covered with the passivation layer 17. The conductive structure 11 is adapted to electrically connect to a corresponding pad 15 of the semiconductor integrated circuit 1 through a corresponding opening 170 of the openings 170, and in other words, each of the pads 15 would be electrically connected with and directly connected to a corresponding conductive structure 11. It should be noted that the opening 170 of this embodiment is a rectangle, and people skilled in this art may proceed with other aspects having a polygon opening.

The conductive structure 11 comprises a buffering layer 111, an under bump metallurgy (UBM) layer 113 and a bump 115. The buffering layer 111 is formed on the passivation layer 17 without fully blocked the corresponding opening 170. More particularly, the buffering layer 111 is partially formed on the corresponding pad 15 to cover at least one portion of corresponding opening 170 as shown in FIGS. 1(a) and 1(b). The buffering layer 111 covers around the corresponding opening 170 and defines a buffering layer opening 111′. Since the opening 170 of this embodiment is rectangular, the buffering layer 111 would also cover four sides of the corresponding opening 170 in this embodiment to form the buffering layer opening 111′. The UBM layer 113 is substantially formed on a part of the buffering layer opening 111′ and in the corresponding opening 170 for electrically connecting to the corresponding pad 15. Additionally, the UBM layer 113 continuously extends over and covers a peripheral portion of the buffering layer 111. The bump 115 is formed on the UBM layer 113. In order to achieve a proper electrical connection, the buffering layer 111 has a buffer thickness, the bump 115 has a bump thickness, and the buffer thickness is thicker than ⅓ of the bump thickness. Furthermore, the buffer thickness is at least 3 μm.

The buffering layer 111 is made of epoxy, polyimide (PI), benzocyclobutene (BCB), solder mask (SM), solder resist (SR), or a combination thereof or the like. People skilled in this are may use SINR (i.e. a product of Shin-Etsu Chemical Corp) as the material of the buffering layer.

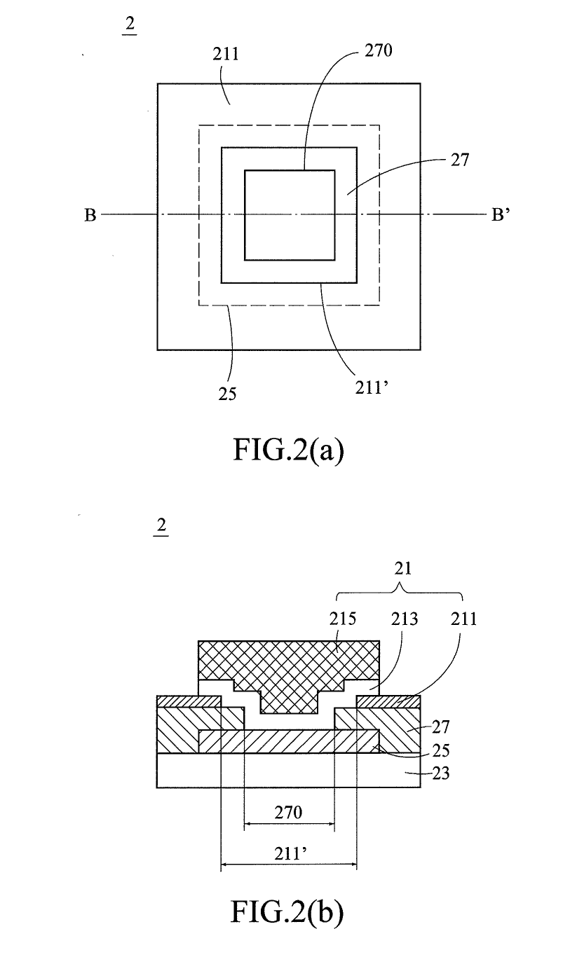

As shown in FIG. 2(a) and FIG. 2(b), a semiconductor integrated circuit 2 with the conductive structure 21 is the second embodiment of the present invention. The semiconductor integrated circuit 2 has a substrate 23, a plurality of pads 25 and a passivation layer 27. In the conductive structure 21 of this embodiment, the buffering layer 211 may be only formed on the passivation layer 27 without covering the corresponding opening 270, and is formed around the corresponding opening 270 to define a buffering layer opening 211′. The UBM layer 213 continuously extends over and covers the peripheral portion of the buffering layer 211, the peripheral portion of the passivation layer 27 and the pad through the corresponding opening 270. FIG. 2(a) is the top view of a part of the semiconductor integrated circuit 2 shown in FIG. 2(b). For the purpose of clarity, only a buffering layer 211 among all elements of the conductive structure 21, is illustrated and the UBM layer 213 and the bump 215 are omitted. In other words, FIG. 2(a) is the top view of the semiconductor integrated circuit 2 without the UBM layer 213 and the bump 215.

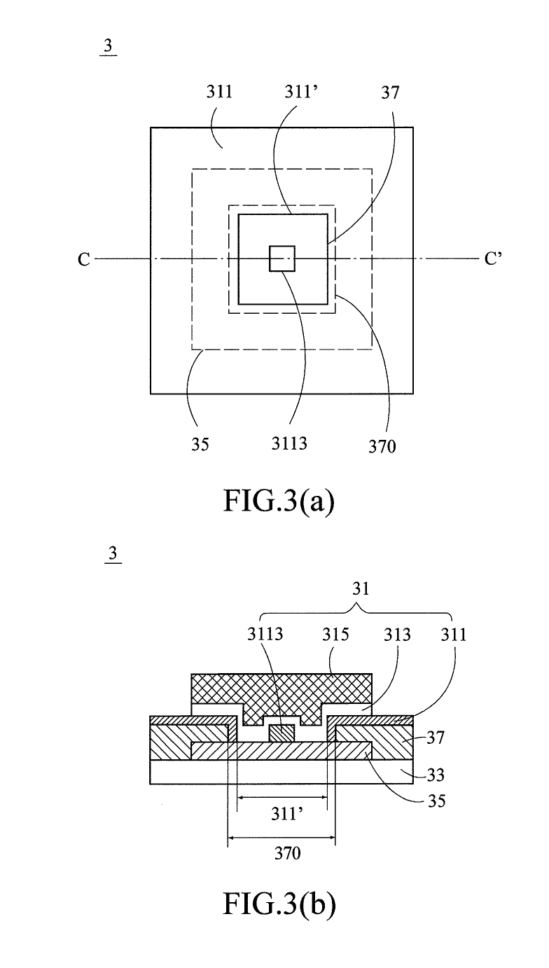

The detailed descriptions and the relationship between the elements of the second embodiment are similar to the first embodiment, would be omitted for clarity and conciseness. Referring to FIGS. 3(a) and 3(b) show a semiconductor integrated circuit 3, having a substrate 33, a plurality of pads 35 and a passivation layer 37, of the third embodiment of the present invention. For the purpose of clarity, in FIG. 3(a), only a buffering layer 311 among all elements of the conductive structure 31 is illustrated and the UBM layer 313 and the bump 315 are omitted. In other words, FIG. 3(a) is the top view of the semiconductor integrated circuit 3 without the UBM layer 313 and the bump 315. Distinct from the first embodiment, the third embodiment's the conductive structure 31 further comprises a central buffering block 3113, formed in the central of both the corresponding opening 370 and the buffering layer opening 311′ on the pad 35, and the UBM layer 313 extending over and covering the central buffering block 3113. The function of the central buffering block 3113 is to uniformly absorb the stress on the conductive structure 31. In this embodiment, the central buffering blocks 3113 are placed in the central of the pads 35.

In some aspects, the conductive structure can be implemented with several central buffering blocks, scattered on the pads, could further buffer the stress on the conductive structure. The aforesaid embodiments or the following embodiments can be disposed with such central buffering block on the pads as well.

The detailed descriptions and the relationship between the elements of the second embodiment are similar to the first embodiment, would be omitted for clarity and conciseness.

Moreover, similarly to the buffering layer 311, the central buffering block 3113 is also made of epoxy, polyimide (PI), benzocyclobutene (BCB), solder mask (SM), solder resist (SR), or a combination thereof or the like. People skilled in this are may use SINR (i.e. a product of Shin-Etsu Chemical Corp) as the material of the buffering layer. Furthermore, the material of the central buffering block 3113 is not necessary limit to be as same as the buffering layer 311.

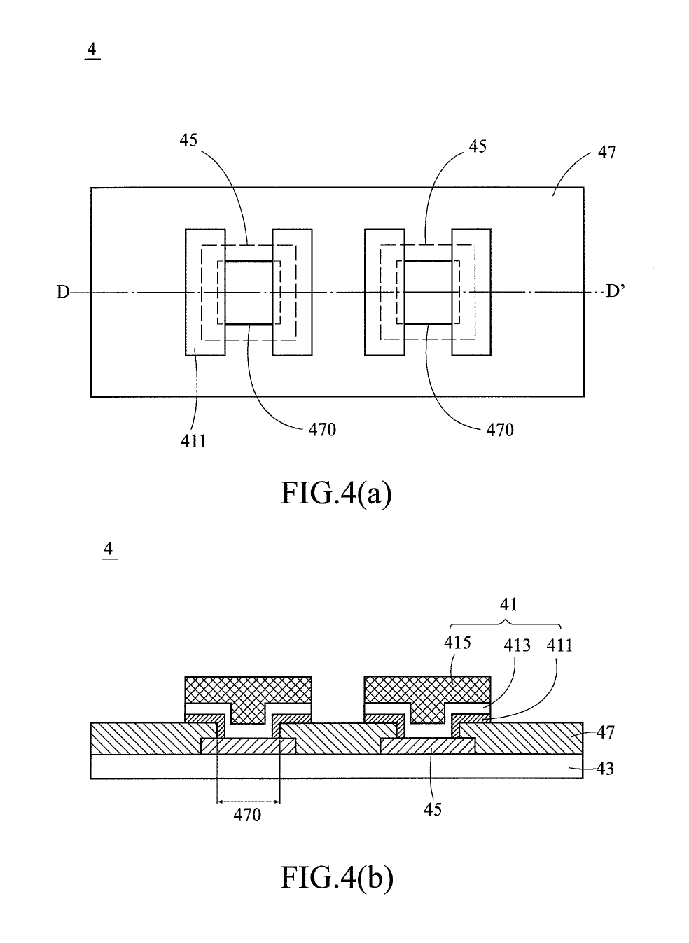

Yet there also exist another embodiment of the semiconductor integrated circuit 4 as shown in FIGS. 4(a) and 4(b). The semiconductor integrated circuit 4 has a substrate 43, a plurality of pads 45 and a passivation layer 47. The conductive structure 41 comprises a buffering layer 411, a UBM layer 413 and a bump 415. The buffering layer 411 of the fourth embodiment is also partially formed on the corresponding pad 45 to cover at least one portion of the corresponding opening 470 without fully blocking the corresponding opening 470, and the UBM layer 413 continuously extends over and covers a peripheral portion of the buffering layer 411. The essential difference between this embodiment and the aforementioned embodiments is that the buffering layer 411 is formed on a part of the passivation layer 47 and covers only two sides of corresponding opening 470. The opening 470 of this embodiment is a rectangle, and the buffering layer 411 covers only two opposing sides of the rectangular opening 470. The detailed relationship within the conductive structure 41 had been disclosed as above, would not be repeated herein.

The detailed descriptions and the relationship between the elements of the second embodiment are similar to the first embodiment, would be omitted for clarity and conciseness.

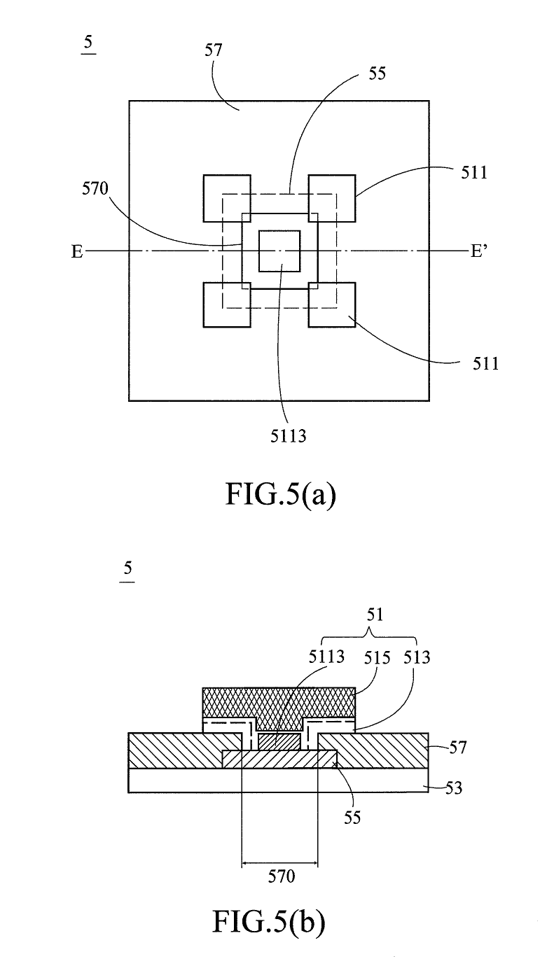

FIGS. 5(a) and 5(b) show the fifth embodiment of this present invention, and FIG. 5(b) is the cross-section view of a part of the semiconductor integrated circuit 5 along a line E-E′ of FIG. 5(a). The semiconductor integrated circuit 5 of the fifth embodiment of this present invention has a substrate 53, a plurality of pads 55 and a passivation layer 57, and the conductive structure 51 comprises a buffering layer 511, a UBM layer 513, a bump 515 and a central buffering block 5113.

The most prominent difference of this embodiment from other embodiments is that the buffering layer 511 covers at least one corner of the corresponding opening 570. More specifically, the opening 570 presented in this embodiment is a rectangle, and the buffering layer 511 covers four corners of the corresponding opening 570 as shown in FIG. 5(a), which shows the top view of the semiconductor integrated circuit 5 without the UBM layer 513 and the bump 515.

The detailed descriptions and the relationship between the elements of the second embodiment are similar to the first embodiment, would be omitted for clarity and conciseness.

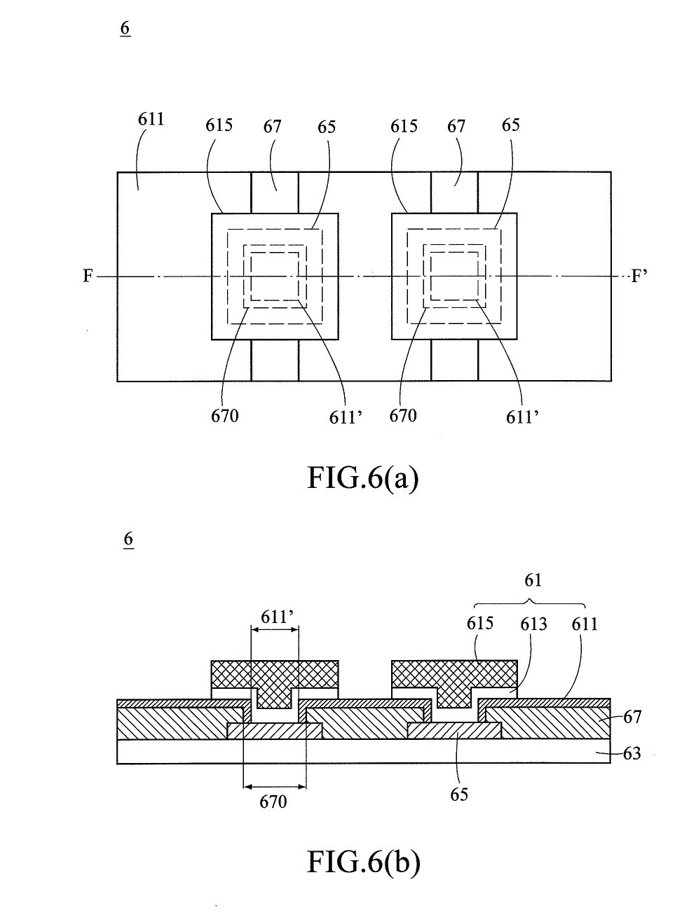

FIG. 6(a) and FIG. 6(b) are the schematic view and the cross sectional view of a semiconductor integrated circuit 6 with the conductive structure 61 of the sixth embodiment of the present invention. The semiconductor integrated circuit 6 has a substrate 63, a plurality of pads 65 and a passivation layer 67. The conductive structure 61 comprises a buffering layer 611, a UBM layer 613 and a bump 615. The sixth embodiment is similar to the first embodiment, and the difference therebetween is that the buffering layers 611 of the conductive structure 61 of the sixth embodiment only covers only two opposite sides of the corresponding opening 670 to define a buffering layer opening 611′.

As noted above, other aspect of the sixth embodiment may be proceeded by people skilled in this art. The conductive structure may also comprise a central buffering block, formed in the corresponding opening on the pad. The related description has been depicted in the abovementioned embodiments.

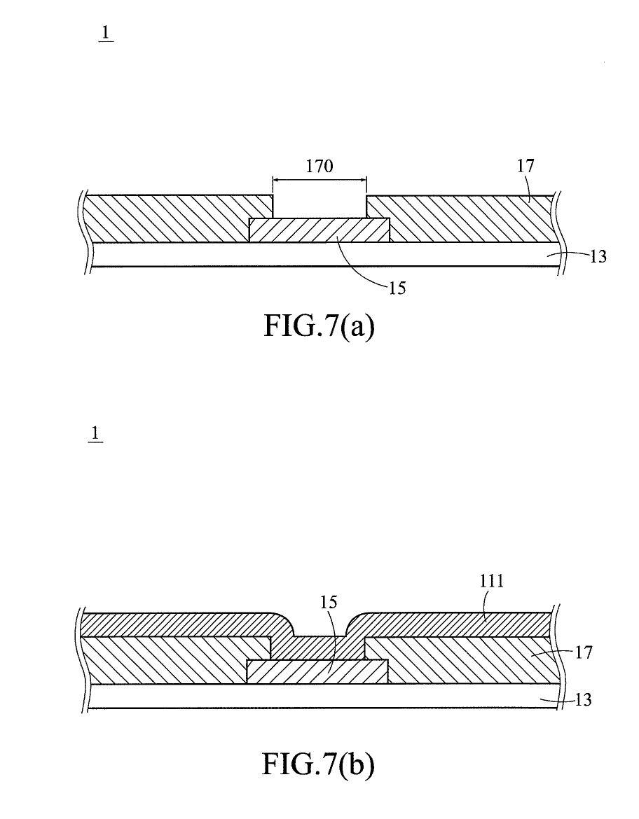

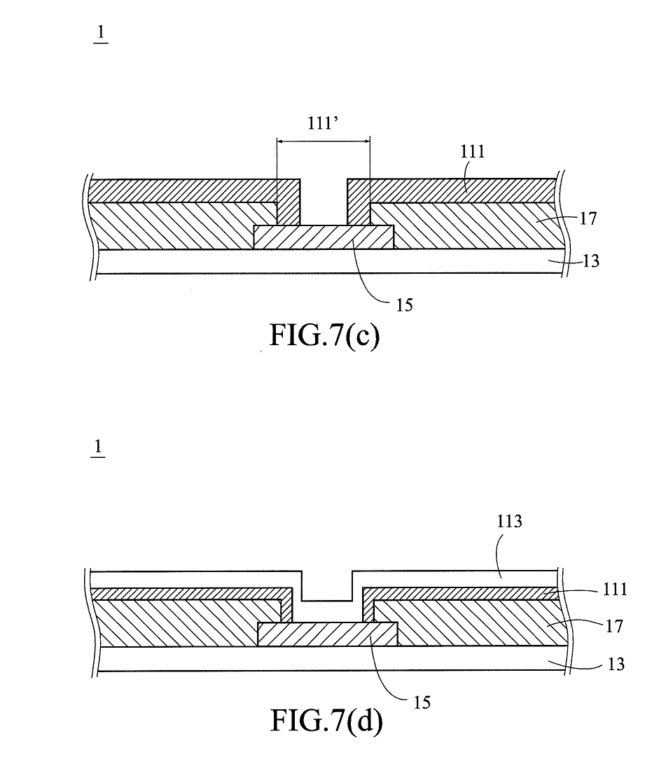

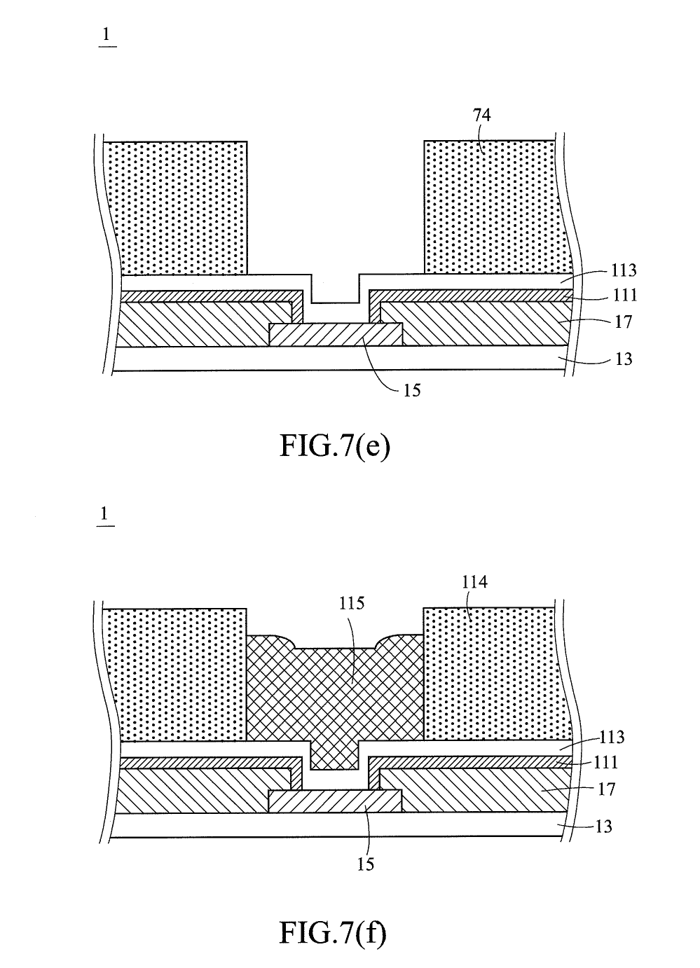

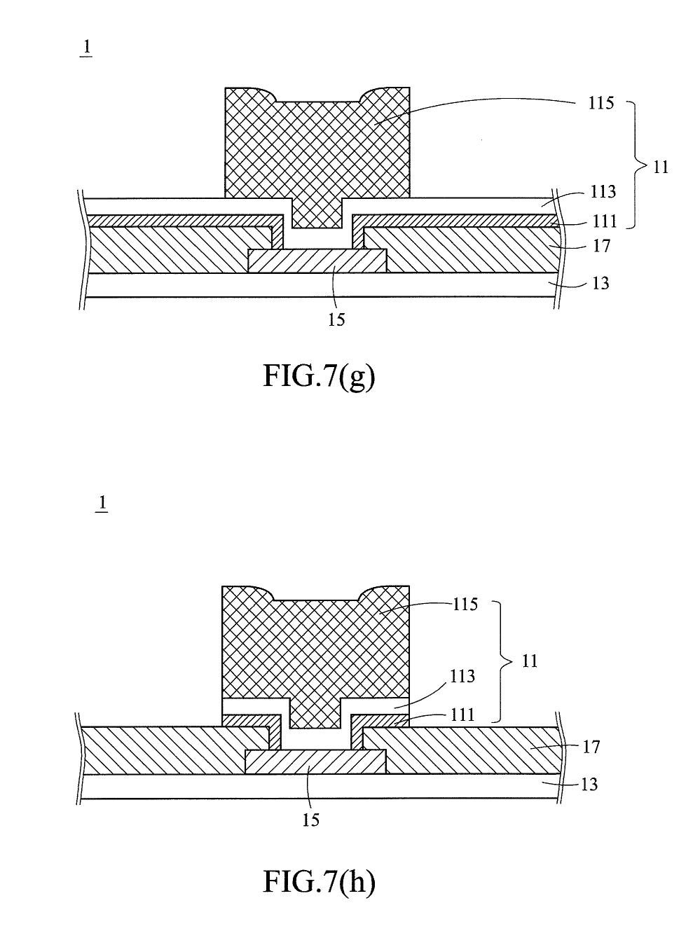

FIGS. 7(a) to 7(h) depict a process flow for forming the conductive structure 11 on the semiconductor integrated circuit 1 in accordance with the first embodiment of this invention

As depicted in FIG. 7(a), the semiconductor integrated circuit 1 comprises a substrate 13, a plurality of pads 15 and a passivation layer 17. The pads 15 are disposed on the substrate 13 (only one pad 15 is shown). The passivation layer 17 extends over and covers a part of the substrate 13 and around each of the pads 15 in order to define a plurality of openings 170 on the substrate 13. These openings 170 would be used for the electrical connection between the conductive structure 11 and the pads 15.

As shown in FIG. 7(b), the buffering layer 111 is formed on the passivation layer 17 and covers the openings 170. While coating the buffering layer 111, a concave would be naturally formed above the corresponding opening 170 in the buffering layer 111. In this embodiment, the buffering layer 111 is made of a material of epoxy, polyimide (PI), benzocyclobutene (BCB), solder mask (SM), solder resist (SR) or a combination thereof or the like. People skilled in this are may also use SINR (i.e. a product of Shin-Etsu Chemical Corp) as the material of the buffering layer.

Subsequently, a portion of the buffering layer 111 on the corresponding opening 170 is removed by the conventional exposure and development process in FIG. 7(c). After the removal, the central portion of the corresponding pad 15 is selectively exposed. In other words, the buffering layer 111 covers around the corresponding opening 170 without fully blocking the corresponding opening 170. In brief, the periphery of the opening 170 is covered by the buffering layer 111 to absorb the stress while forming the other elements of the conductive structure 11. Additionally, the buffering layer 111 dose not only function as an adhesive structure between the bump 115 and the UBM layer 113, but also lessens or moderates the undercut effect.

Next, referring to FIG. 7(d), the UBM layer 113 is substantially formed in the corresponding opening 170 for electrically connecting to the corresponding pad 15. The UBM layer 113 could be a titanium/tungsten alloy conductive layer. While forming on the buffering layer 111 and the corresponding pad 15, a concave is naturally formed in the UBM layer 113. Furthermore, since the UBM layer 113 continuously extends over and covers a peripheral portion of the buffering layer 111, a reliable conductive path necessary for the subsequent formed bump 115 is provide. In some embodiments, an addition metal layer could be provided on the UBM layer 113 for a smoother surface for formation of the bump 115, and a thicker UBM layer 113 could also ensure a more stable resistance to facilitate the subsequent electroplating step.

A photoresist layer 74 is then coated onto the entire conductive structure 11. A portion of the photoresist layer 74 had been etched or removed as shown in FIG. 7(e) for the following formation of the bump 115. Then, as shown in FIG. 7(f), the bump 115 is formed by electroplating to overlap and electrically connect to the UBM layer 113. In this embodiment, the bump 115 is made of gold. After the formation of the bump 115, the photoresist layer 74 is removed as shown in FIG. 7(g). At the same time, the unnecessary portion of the UBM layer 113 and buffering layer 111 are removed, leaving only the portion under the bump 115, as shown in FIG. 7(h).

Overall, the present invention comprises a buffering layer in order to absorb the pressure and stress during the operation of the conductive structure. In some embodiments, a central buffering block is further provided to enhance this character. Thus, by utilizing a buffer structure in the conductive structure could fulfill the objectives to avoid and lessen the undercut effect, and a firmly electrical connection between the semiconductor integrated circuit and a circuit board is thereby provided.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A conductive structure for a semiconductor integrated circuit, the semiconductor integrated circuit having a substrate, a plurality of pads and a passivation layer, the pads being disposed on the substrate, the passivation layer extending over and covering a part of the substrate and around each of the pads to define a plurality of openings, in which the conductive structure electrically connects to a corresponding pad of the pads through a corresponding opening of the openings, the conductive structure comprising:
a buffering layer, being formed on the passivation layer without fully blocking the corresponding opening;
an under bump metallurgy (UBM) layer, being substantially formed in the corresponding opening for being electrically connected to the corresponding pad, wherein the UBM layer continuously extends over and covers a peripheral portion of the buffering layer; and
a bump, being formed on the UBM layer.

2. The conductive structure as claimed in claim 1, further comprising a central buffering block, formed in the corresponding opening on the pad, and the UBM layer extending over and covering the central buffering block.

3. The conductive structure as claimed in claim 1, wherein the buffering layer is partially formed on the corresponding pad to cover at least one portion of the corresponding opening without fully blocking the corresponding opening, and the UBM layer continuously extends over and covers a peripheral portion of the buffering layer.

4. The conductive structure as claimed in claim 3, wherein the buffering layer covers two sides of the corresponding opening.

5. The conductive structure as claimed in claim 3, wherein the corresponding opening is a polygon, and the buffering layer covers at least one corner of the corresponding opening.

6. The conductive structure as claimed in claim 3, wherein the buffering layer covers around the corresponding opening.

7. The conductive structure as claimed in claim 1, wherein the buffering layer is only formed on the passivation layer without covering the corresponding opening, and the UBM layer continuously extends over and covers a peripheral portion of the passivation layer.

8. The conductive structure as claimed in claim 7, wherein the buffering layer covers around the corresponding opening.

9. The conductive structure as claimed in claim 2, wherein the buffering layer and the central buffering block are made of a material of epoxy, polyimide (PI), benzocyclobutene (BCB), solder mask (SM), solder resist (SR), or a combination thereof.

10. The conductive structure as claimed in claim 2, wherein each of the buffering layer and the central buffering block has a buffer thickness, the bump has a bump thickness, and the buffer thickness is thicker than ⅓ of the bump thickness.

11. The conductive structure as claimed in claim 2, wherein each of the buffering layer and the central buffering block has a buffer thickness, and the buffer thickness is at least 3 μm.
